(19) United States
(12) Patent Application Publication
(10) Pub. No.: US 2025/0365929 A1
(43) Pub. Date: Nov. 27, 2025

(54) DRAM DEVICE WITH SUB 4F2 STRUCTURE COMPRISING SWITCHING INSULATING LAYER AND MULTILAYER STRUCTURE OF WORD LINE

(71) Applicant: TAESUNG ENVIRONMENTAL RESEARCH INSTITUTE CO., LTD., Ulsan (KR)

(72) Inventors: Gi Yeol YUN, Ulsan (KR); Seok Man Kim, Ulsan (KR); Chai Rok Lim, Ulsan (KR); Hyeok-je Jeong, Gimhae-si (KR); Myung-Kon Jo, Ulsan (KR)

(73) Assignee: TAESUNG ENVIRONMENTAL RESEARCH INSTITUTE CO., LTD., Ulsan (KR)

(21) Appl. No.: 18/678,777

(22) Filed: May 30, 2024

(30) Foreign Application Priority Data
May 21, 2024 (KR) 10-2024-0065688

(51) Int. Cl. H10B 12/00

(52) U.S. Cl. CPC H10B 12/315

(57) ABSTRACT

A DRAM device, including: a substrate; a plurality of bit lines located on the substrate, and disposed parallel to each other in a first horizontal direction; a plurality of word lines located on the bit line, and disposed parallel to each other in a second horizontal direction substantially perpendicular to the first horizontal direction; a plurality of channel patterns arranged in a honeycomb structure on the bit line, the plurality of channel patterns; a gate insulating pattern located between the plurality of channel patterns and the plurality of word lines; a plurality of switching insulating layers each formed on an upper surface of each of the plurality of channel patterns, at least a portion of which has a thickness that an electron can penetrate upon application of a voltage; and a plurality of control electrodes disposed parallel to each other to connect the plurality of switching insulating layers.

### TECHNICAL FIELD

The present invention relates to a DRAM device. More specifically, the present invention relates to a DRAM device with sub 4F2 structure comprising a multilayer structure of a word line and a switching insulating layer.

### BACKGROUND ART

As the density of semiconductor memory devices increases, the cell structure is changing from 8F2 and 6F2 to 4F2 in order to reduce the area occupied by each unit cell in a planar plane. As such, various methods have been suggested to form components such as transistors, bit lines, word lines, capacitors, etc. in response to the decrease in the area of the unit cell. In particular, in order to implement a 4F2 cell structure, a semiconductor device comprising a vertical channel transistor that induces a vertical channel by disposing a source and a drain vertically has been suggested (non-patent reference 1).

However, in the semiconductor device of non-patent reference 1, the vertical pillar is in direct contact with the cell capacitor, causing leakage current to flow during data storage. Accordingly, the semiconductor device has a short retention time, requiring frequent data refresh operations and high power consumption.

Meanwhile, in the field of semiconductor devices, there has been a continuous progress in the direction of reducing the minimum feature size F and pursuing smaller cell layouts in order to increase the capacity per unit area. Recently, however, the increase in capacity per unit area by reducing the minimum feature size F has reached a physical limitation, and accordingly, it is no longer possible to expect an increase in capacity per unit area by the semiconductor device of non-patent reference 1.

### PRIOR ART REFERENCE

### Non-Patent Reference

(Non-patent reference 1) Chung et al., “Novel 4F2 DRAM Cell with Vertical Pillar Transistor (VPT)” 2011 Proceedings of the European Solid-State Device Research Conference (ESSDERC), 2011

### SUMMARY OF INVENTION

### Technical Task

One of the many objects of the present invention is to provide a vertical channel transistor capable of extending retention time and a DRAM device comprising the same.

In addition, another object of the many objects of the present invention is to provide a vertical channel transistor capable of increasing the capacity per unit area and a DRAM device comprising the same.

### Means for Solving Technical Task

According to an aspect, a DRAM device, comprising: a substrate; a plurality of bit lines located on the substrate, and disposed parallel to each other in a first horizontal direction at predetermined intervals; a plurality of word lines located on the bit line, and disposed parallel to each other in a second horizontal direction substantially perpendicular to the first horizontal direction at predetermined intervals; a plurality of channel patterns arranged in a honeycomb structure on the bit line, the plurality of channel patterns each extending in a vertical direction; a gate insulating pattern located between the plurality of channel patterns and the plurality of word lines; a plurality of switching insulating layers each formed on an upper surface of each of the plurality of channel patterns, at least a portion of which has a thickness that an electron can penetrate upon application of a voltage; and a plurality of control electrodes disposed parallel to each other at predetermined intervals to connect the plurality of switching insulating layers, wherein the plurality of channel patterns located on the single bit line are arranged in zigzag along both edges of the single bit line, and the plurality of channel patterns contacting the single word line are arranged in a straight line, is disclosed.

In an embodiment, the plurality of control electrodes may be disposed parallel to each other in the second horizontal direction.

In an embodiment, the control electrode may have a thickness greater than the thickness of the switching insulating layer.

In an embodiment, the switching insulating layer may comprise at least one selected from the group consisting of silicon oxide (SiO₂), titanium oxide (TiO₂), aluminum oxide (Al₂O₃), nickel oxide (NiO, NiO₂, Ni₂O₃), copper oxide (Cu₂O, CuO), zirconium oxide (ZrO₂), manganese oxide (MnO, MnO₂, Mn₂O₃, Mn₃O₄, Mn₂O₇), hafnium oxide (HfO₂), tungsten oxide (WO, WO₂, WO₃, W₂O₃), tantalum oxide (Ta₂O₅), niobium oxide (Nb₂O₅) and iron oxide (FeO, Fe₂O₃, Fe₃O₄).

In an embodiment, the DRAM device may further comprise a spacer layer formed on at least a portion of a side surface of the plurality of channel patterns to electrically insulate the plurality of channel patterns from the plurality of control electrodes.

In an embodiment, each of the plurality of channel patterns may comprise an upper electrode and a lower electrode, wherein the lower electrode may be in contact with the bit line.

In an embodiment, the DRAM device may further comprise a gate electrode arranged between the word line and the gate insulating pattern.

### Effect of Invention

The DRAM device according to an aspect of the present invention suppresses leakage current generation and extends retention time

In addition, the DRAM device according to an aspect of the present invention has excellent data retention characteristics and low power consumption.

Furthermore, the DRAM device according to an aspect of the present invention facilitates the increase in the capacity per unit area.

The effects of an aspect of the present specification are not limited to the above-mentioned effects, and it should be understood that the effects of the present specification include all effects that could be inferred from the configuration described in the detailed description of the specification or the appended claims.

### BRIEF DESCRIPTION OF DRAWINGS

FIG. 1 is a perspective view of a vertical channel transistor according to an embodiment of the present invention;

FIG. 2 is a cross-sectional view taken along A-A′ of FIG. 1;

FIG. 3 is a cross-sectional view taken along B-B′ of FIG. 1;

FIG. 4 is a schematic plan view of the vertical channel transistor of FIG. 1;

FIG. 5 is a perspective view of a DRAM device comprising the vertical channel transistor of FIG. 1;

FIG. 6 is a cross-sectional view of a vertical channel transistor according to a first modification example;

FIG. 7a is a plan view of a DRAM device comprising a vertical channel transistor with conventional 4F2 structure; and

FIG. 7b is a plan view of a DRAM device comprising a vertical channel transistor wherein (3) the intervals between adjacent word lines is reduced to one-half (½) compared to (1) the width of the word line, (2) the width of the bit line, and (4) the intervals between adjacent bit lines.

FIG. 8 illustrates an energy band inside a switching insulating layer.

### BEST MODE FOR CARRYING OUT THE INVENTION

Hereinafter, an aspect of the present invention will be explained with reference to the accompanying drawings. However, the present invention may be implemented in various different forms, and is not intended to be limited to the embodiments set forth herein.

Throughout the specification, it will be understood that when a portion is referred to as being “connected” to another portion, it can be “directly connected to” the other portion, or “indirectly connected to” the other portion having intervening portions present. In addition, when a member is referred to as being located “on,” “on an upper part of,” “on an upper end of,” “under,” “on a lower part of,” “on a lower end of” another member, this includes not only when a member is adjacent to another member, but also when there is another member between the two members.

Throughout this specification, when a component “includes” an element, unless there is another opposite description thereto, it should be understood that the component does not exclude another element but may further include another element.

The embodiments described herein will be described with reference to the cross-sectional views and/or schematic drawings, which are idealized illustrations of the present invention. In addition, throughout the specification, like reference numerals refer to like components. Detailed descriptions of known features and configurations which may obscure the gist of the present invention are hereby omitted, and each component in each of the drawings illustrating the present invention may be somewhat enlarged or reduced in size for ease of description.

Further, embodiments of the present invention are not limited to specific shapes illustrated, but also include variations in shape produced by the manufacturing process.

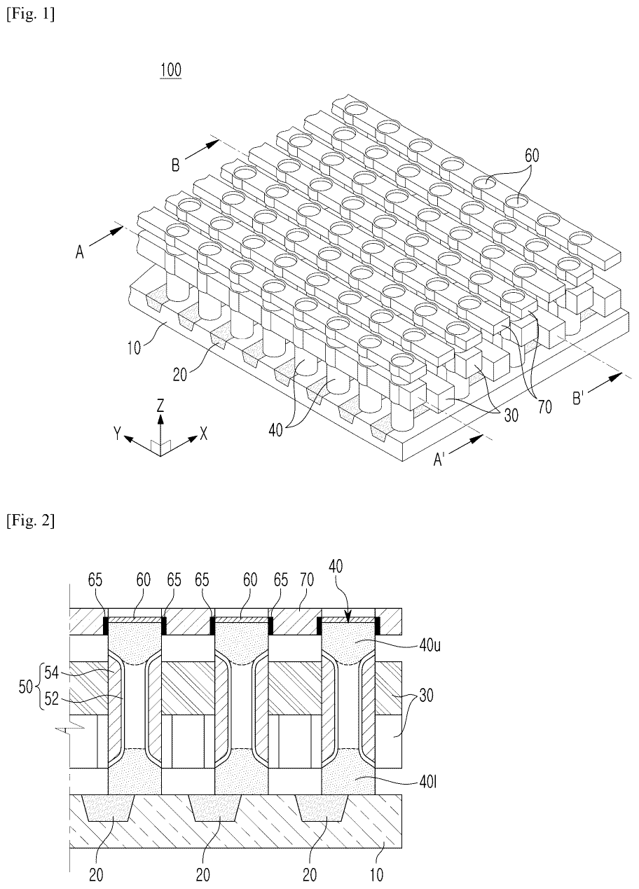

FIG. 1 is a perspective view of a vertical channel transistor according to an embodiment of the present invention.

Referring to FIG. 1, a vertical channel transistor 100 according to an embodiment of the present invention comprises: a substrate 10; a plurality of bit lines 20 located on the substrate 10, and disposed parallel to each other in a first horizontal direction at predetermined intervals; a plurality of word lines 30u and 30l located on the bit line 20, and disposed parallel to each other in a second horizontal direction substantially perpendicular to the first horizontal direction at predetermined intervals; a plurality of channel patterns 40 arranged in a honeycomb structure on the bit line 20, the plurality of channel patterns each extending in a vertical direction; a gate insulating pattern (not shown) located between the plurality of channel patterns 40 and the plurality of word lines 30u and 30l; a plurality of switching insulating layers 60 each formed on an upper surface of each of the plurality of channel patterns 40, at least a portion of which has a thickness that an electron can penetrate upon application of a voltage; and a plurality of control electrodes 70 disposed parallel to each other at predetermined intervals to connect the plurality of switching insulating layers 60.

The vertical channel transistor 100 according to an embodiment of the present invention has a plurality of bit lines 20 and a plurality of word lines 30u and 30l intersect each other. Each bit line 20 may extend in a first horizontal direction (e.g., an X-axis direction), and each word line 30u and 30l may extend in a second horizontal direction (e.g., a Y-axis direction) intersecting the first horizontal direction.

A plurality of channel patterns 40 are disposed at the points where the plurality of bit lines 20 and the plurality of word lines 30u and 30l intersect.

Electrodes (not shown) are formed, respectively, at an upper part and a lower part of the plurality of channel patterns 40. A gate (not shown) is formed to enclose a side surface between the upper electrode and the lower electrode, and the gate may comprise a gate insulating pattern and a gate conducing pattern.

The plurality of word lines 30u and 30l comprise a first word line 30u and a second word line 30l respectively disposed at different heights, and the first and second word lines are provided alternating with each other in the first horizontal direction (e.g., an X-axis direction).

In the conventional vertical channel transistor, the plurality of word lines are disposed side by side at substantially the same height, and thus there are physical limitations to increasing the capacity per unit area.

However, in the present invention, since adjacent word lines are disposed at different heights, the minimum feature size F may be easily reduced, thereby increasing the capacity per unit area and improving the density.

The first and second word lines 30u and 30l may be formed independently of each other of at least one material among metal, semiconductor and alloy, and may be formed of the same material or may be formed of different materials.

A spacer (not shown) may be provided at a side wall of the first and second word lines 30u and 30l. The spacer may prevent contact with other channel patterns 40 which are not interconnected by the first and second word lines 30u and 30l.

FIG. 2 is a cross-sectional view taken along A-A′ of FIG. 1.

The substrate 10 may include, for example, a group IV semiconductor material such as silicon (Si), germanium (Ge), silicon germanium (SiGe), silicon carbide (SiC), a group III-V semiconductor material such as gallium arsenide (GaAs), indium arsenide (InAs), indium phosphide (InP), an oxide semiconductor, a nitride semiconductor, a nitrogen oxide semiconductor, etc. Specifically, the substrate may be a silicon substrate doped with n-type impurities, but is not limited thereto.

Each of the plurality of channel patterns 40 may extend substantially vertically from the substrate 10. Here, each channel pattern 40 may protrude substantially vertically from an upper surface of the substrate 10. Each channel pattern 40 is integrally formed with the substrate 10, and thus may comprise the same semiconductor material as the substrate 10.

Each of the plurality of channel patterns 40 may comprise a source region as an upper electrode 40u and a drain region as a lower electrode 40l. The lower electrode 40l may be electrically connected to the bit line 20, and the upper electrode 40u may be electrically connected to a capacitor (not shown) which will be described later. The positions of the source region and the drain region may vary as needed, and the upper electrode 40u may function as a drain region and the lower electrode 40l may function as a source region.

In the channel pattern 40, the region between the upper electrode 40u and the lower electrode 40l, which is the body region (not shown), has the same polarity as the substrate 10, and the upper electrode 40u and the lower electrode 40l have a different polarity from the substrate 10. For example, when the substrate 10 is a p-type semiconductor substrate, the body region has a p-type polarity, and the upper electrode 40u and the lower electrode 40l have an n-type polarity. In this case, the upper electrode 40u and the lower electrode 40l may be formed by implanting n-type impurity ions into each of the upper end and the lower end of the channel pattern 40 and performing drive-in diffusion.

A gate 50 is formed between the upper electrode and the lower electrode to enclose a side surface of the channel pattern 40, and the gate 50 may comprise a gate insulating pattern 52 and a gate conducing pattern 54.

In an example, at least a portion of each channel pattern 40 may be in direct contact with the substrate 10. In this case, a back bias may be imparted to each channel pattern 40 to suppress the floating body effect. The contact area of each channel pattern 40 with the substrate 10 is not particularly limited, but may be, for example, any one of a periphery part or a center part of each channel pattern 40.

The bit lines 20 are arranged to extend along a first horizontal direction (e.g., an X-axis direction) on a lower part of the lower electrode 40l, and each bit line 20 may electrically connect the lower electrode 40l arranged along the first horizontal direction. The bit line 20 is formed in the interior of the substrate 10, and thus may comprise the same semiconductor material as the substrate 10.

Each of the plurality of the first word lines 30u is provided at a height corresponding to an upper part of a gate 50 formed on a side surface of the channel pattern 40. Additionally, each first word line 30u may be provided to enclose at least a portion of the upper part of the gate 50.

The first word line 30u may comprise a conductive material. For example, the first word line 30u may comprise at least one of metal, semiconductor and alloy. Specifically, the first word line 30u may comprise one or more metals selected from the group consisting of aluminum, tungsten, molybdenum, titanium, and tantalum, and one or more semiconductors selected from the group consisting of group IV semiconductors, group II-v semiconductors, oxide semiconductors, nitride semiconductors, and nitrogen oxide semiconductors, but is not limited thereto.

A plurality of switching insulating layers 60 are each formed on an upper surface of each of the plurality of channel patterns 40, at least a portion of which has a thickness that an electron can penetrate upon application of an external voltage.

According to conventional vertical channel transistors, the channel pattern is in direct contact with the cell capacitor, causing leakage current to flow during data storage. Accordingly, the semiconductor device has a short retention time, requiring frequent data refresh operations.

However, according to the present invention, the switching insulating layer 60 is formed on the upper surface of the channel pattern 40. Accordingly, current flows between the channel pattern and the capacitor by tunneling, channeling, etc., upon application of an external voltage during data recognition, whereas leakage current generation is suppressed during data storage, resulting in extended retention time. Thereby, cells can normally operate during data storage and during data recognition, data retention characteristics are improved, and also power consumption can be reduced. In addition, extended retention time allows a cell capacitor to have a smaller height, which facilitates manufacturing and scaling down.

The switching insulating layer 60 may comprise, but is not limited to, at least one selected from the group consisting of silicon oxide (SiO₂), titanium oxide (TiO₂), aluminum oxide (Al₂O₃), nickel oxide (NiO, NiO₂, Ni₂O₃), copper oxide (Cu₂O, CuO), zirconium oxide (ZrO₂), manganese oxide (MnO, MnO₂, Mn₂O₃, Mn₃O₄, Mn₂O₇), hafnium oxide (HfO₂), tungsten oxide (WO, WO₂, WO₃, W₂O₃), tantalum oxide (Ta₂O₅), niobium oxide (Nb₂O₅) and iron oxide (FeO, Fe₂O₃, Fe₃O₄).

The thickness of the switching insulating layer 60 is not particularly limited as long as it can provide a pathway for electrons to move by tunneling, channeling, etc. The switching insulating layer 60 may have a thickness, e.g., 1 nm or less.

The plurality of control electrodes 70 are disposed parallel to each other at predetermined intervals to connect the plurality of switching insulating layers 60. The plurality of control electrodes 70 may be formed to enclose a side surface of each switching insulating layer 60. The plurality of control electrodes 70, which are for controlling the movement of electrons through the switching insulating layer, modify an energy band of the switching insulating layer 60 during data recognition, thereby helping electrons to move by tunneling, channeling, etc.

In the case where only the switching insulating layer 60 is formed between the channel pattern 40 and the capacitor, sufficient current flow can hardly be expected during data recognition. However, according to the present invention, a plurality of control electrodes 70 connecting the plurality of switching insulating layers 60 are arranged, and current is applied to the plurality of control electrodes 70 during data recognition, thereby achieving smooth current flow.

In an example, a plurality of control electrodes 70 may be disposed parallel to each other in a second horizontal direction. In other words, the plurality of control electrodes 70 may extend in the same direction as a plurality of word lines 30u and 30l. In this case, the flow of current can be controlled smoothly by applying current to control electrodes 70 arranged on word lines 30u and 30l to which current is applied, while not applying current to control electrodes 70 arranged on word lines 30u and 30l to which current is not applied.

In an example, the control electrode 70 may have a thickness greater than the thickness of the switching insulating layer 60, e.g., a thickness of greater than 1 nm and 2 nm or less, but is not limited thereto. In this case, electrons in the switching insulating layer 60 may move smoothly by tunneling, channeling, etc.

In an example, a spacer layer 65 may be further comprised, which is formed on at least a portion of a side surface of the plurality of channel patterns 40 (e.g., an upper part of the channel pattern 40) to electrically insulate the plurality of channel patterns 40 from the plurality of control electrodes 70. The spacer layer 65 may extend to at least a portion of a side surface of the switching insulating layer 60, but is not limited thereto.

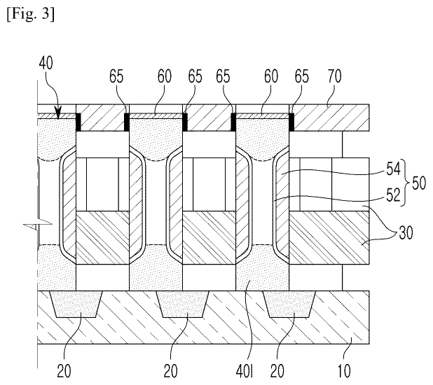

FIG. 3 is a cross-sectional view taken along B-B′ of FIG. 1.

Referring to FIG. 3, the plurality of channel patterns 40 are in common contact with the second word line 30l, and specifically, each second word line 30l is provided at a height corresponding to the lower part of the gate 50 formed on a side surface of the channel pattern 40. Additionally, each first word line 30u is provided to enclose at least a portion of the lower part of the gate 50.

The second word line 30l is disposed at a height different from the first word line 30u when viewed in a vertical cross-section, and specifically, the second word line 30l is disposed at a lower position than the first word line 30u. As such, since adjacent first and second word lines 30u and 30l are disposed at different heights, the minimum feature size F may be easily reduced, thereby increasing the capacity per unit area and improving the density.

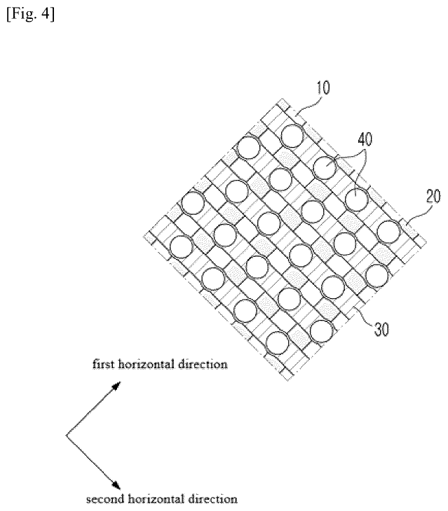

FIG. 4 is a schematic plan view of the vertical channel transistor of FIG. 1.

Referring to FIG. 4, the plurality of channel patterns 40 are disposed in a honeycomb structure on the bit line 20.

Here, a honeycomb structure is a structure in which channel patterns are disposed in the center point and each of the six vertices of a hexagon. Each of the channel patterns located at the six vertices becomes the center point of each of the six neighboring hexagons.

In a honeycomb structure, the hexagon may be an equilateral hexagon, and all six triangles sharing the center point may be equilateral triangles.

As such, as the plurality of channel patterns 40 are disposed in a honeycomb structure, the sub 4F2 structure may be achieved without adjusting the width of the bit line 20, the width of the word lines 30l and 30u, and the intervals between adjacent bit lines 20. For example, assuming that the diameter of each channel pattern 40, the width of the bit line 20, the width of the word lines 30l and 30u, and the intervals between adjacent bit lines 20 are all the same as F, the area of a parallelogram, which is a rectangle connecting the four channel patterns, becomes about 3.464F2(=2F×2F sin 60°). As a result, the sub 4F2 structure may be easily achieved without increasing the bit line-to-bit line capacitance, the bit line-to-word line capacitance, and the bit line-to-substrate capacitance, while maintaining the ratio Cb/Cs of bit line capacitance Cb to cell capacitance Cs at the same level as conventionally.

As the plurality of channel patterns 40 have a honeycomb structure, the plurality of channel patterns 40 located on the single bit line are arranged in zigzag along both edges of the single bit line, and the plurality of channel patterns 40 contacting the single word line are arranged in a straight line.

Assuming that the diameter of each channel pattern 40, the width of the bit line 20, and the intervals between adjacent bit lines 20 are all the same as F, the inner half of each channel pattern 40 is located on the bit line 20, and the other half is located on the substrate 10. In this case, since at least a portion of each channel pattern 40 is in direct contact with the substrate 10, a back bias may be imparted to each channel pattern 40 to suppress the floating body effect.

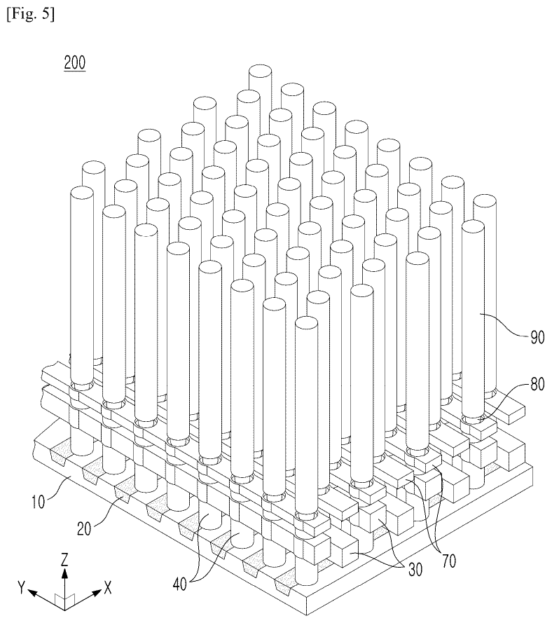

FIG. 5 is a perspective view of a DRAM device comprising the vertical channel transistor of FIG. 1.

Referring to FIG. 5, a capacitor 90 is connected on the vertical channel transistor 100, through which a semiconductor device 200 such as a DRAM may be implemented.

The capacitor 90 may be electrically connected to the channel pattern 40, and a contact plug 80 may be further comprised between the capacitor 90 and the channel pattern 40. The vertical channel transistor 100 may be utilized in a non-memory such as a central processing unit (CPU), as well as in a memory as described above.

The present invention is not particularly limited to methods for manufacturing a vertical channel transistor and a semiconductor device comprising the same, but they may be manufactured by, for example, the following method.

On the substrate 10, a plurality of channel patterns 40 having electrodes 40u and 40l formed at an upper part and a lower part thereof and extending in a substantially vertical direction are formed. The upper electrode 40u of the plurality of channel patterns may be, for example, a source region, and the lower electrode 40l of the plurality of channel patterns may be, for example, a drain region.

The plurality of channel patterns 40 may be arranged in a honeycomb structure on a plane (e.g., an XY plane) of the substrate 10.

Next, a gate 50 is formed to enclose a side surface between the upper electrode 40u and the lower electrode 40l of the plurality of channel patterns 40. The gate 50 may comprise a gate insulating pattern 52 and a gate conducing pattern 54. In this case, preferably, the vertical height of the gate 50 is formed to be greater than at least a sum of vertical heights of the first and second word lines 30u and 30l, which will be mentioned later.

Next, a plurality of bit lines 20 are formed to be in common contact with the lower electrode 40l of the plurality of channel patterns 40. Here, the bit lines 20 may be formed in a first horizontal direction (e.g., an X-axis direction), and the plurality of channel patterns 40 located on the single bit line are arranged in zigzag along both edges of the single bit line.

Next, a plurality of first and second word lines 30u and 30l are formed to be in common contact with the gate 50 formed on a side surface of the plurality of channel patterns 40. Here, the first and second word lines 30u and 30l may be formed in a second horizontal direction (e.g., a Y-axis direction), and may be provided alternating with each other in a first horizontal direction (e.g., an X-axis direction). Each of the first and second word lines 30u and 30l penetrates the center of the plurality of channel patterns 40 arranged in a straight line in the second horizontal direction (e.g., a Y-axis direction).

Next, a plurality of switching insulating layers 60 are each formed on an upper surface of each of the plurality of channel patterns 40, at least a portion of which has a thickness that an electron can penetrate upon application of an external voltage. Here, the thickness that an electron can penetrate upon application of an external voltage may be 1 nm or less, but is not limited thereto.

Next, a spacer layer 65 is formed on at least a portion of a side surface of the plurality of channel patterns 40 (e.g., an upper part of the channel pattern 40). The spacer layer 65 may extend to at least a portion of a side surface of the switching insulating layer 60, but is not limited thereto. The spacer layer 65 may electrically insulate the plurality of channel patterns 40 from a plurality of control electrodes 70.

Next, a plurality of control electrodes 70 are formed to be in common contact with the plurality of switching insulating layer 60. Here, the control electrode 70 may be formed in the same direction as the word lines 30u and 30l, i.e., in the second horizontal direction.

Thereafter, a series of subsequent processes known in the art may be performed one after the other to complete the manufacturing of a vertical channel transistor according to the present invention and a semiconductor device comprising the same.

### First Modification Example

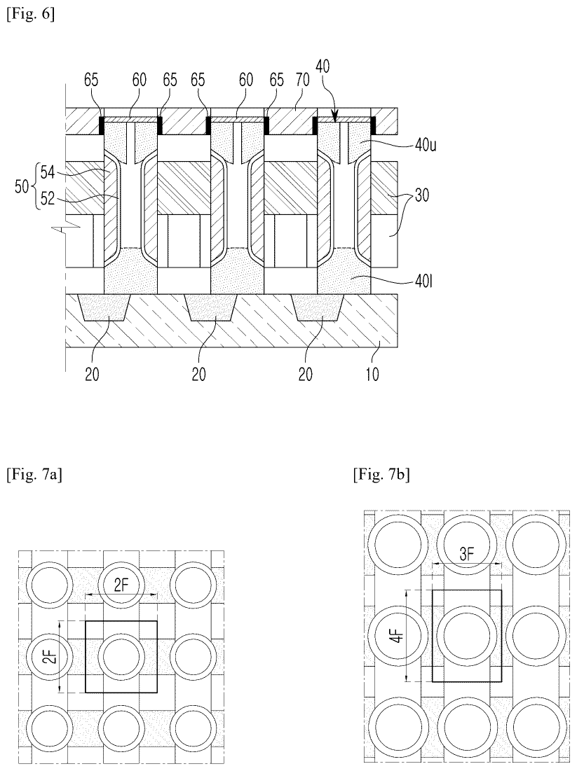

FIG. 6 is a cross-sectional view of a vertical channel transistor according to a first modification example. In FIG. 6, like reference numerals indicate like components in the embodiment described above, and detailed descriptions thereon are omitted or simplified.

The first modification example is characterized in that the body region of the channel pattern 40 penetrates at least a portion of the upper electrode 40u, to be in direct contact with the switching insulating layer 60. In this case, the floating of the switching insulating layer 60 may be avoided.

The body region that penetrates the upper electrode 40u may be formed by an implantation process after forming the upper electrode 40u, or formed by disposing a mask having a predetermined opening pattern on the body region when forming the upper electrode 40u, and then implanting n-type impurity ions thereinto and performing drive-in diffusion.

The contact area of the body region and the switching insulating layer 60 is not particularly limited, but may be, for example, any one of a periphery part and a center part of each channel pattern 40.

The technical reasons why the minimum feature size F can be easily reduced as the adjacent word lines are disposed at different heights are described in more details below.

In the field of DRAM devices, the minimum feature size F is an important element in determining the density and performance of a device. The minimum feature size F means the smallest line width which can be drawn within a semiconductor circuit, and is generally the smallest among (1) the width of a word line, (2) the width of a bit line, (3) the intervals between adjacent word lines, and (4) the intervals between adjacent bit lines.

The smaller the minimum feature size F, the higher the transistor density of a semiconductor chip, the smaller the chip size, and the lower the power consumption. Therefore, in the field of DRAM devices, technological advancements have been directed towards adopting the smallest feature size F.

However, such minimum feature size is not something that can be reduced arbitrarily, and is usually determined by the level of technological advancement at the time of manufacturing. Specifically, the minimum feature size can be determined by the resolution capabilities of photolithography equipment, and the quality and performance of the photoresist.

FIG. 7a is a plan view of a DRAM device comprising a vertical channel transistor with conventional 4F2 structure. In FIG. 7a, (1) the width of the word line, (2) the width of the bit line, (3) the intervals between adjacent word lines, and (4) the intervals between adjacent bit lines are all set to F, resulting in a 4F2 structure.

FIG. 7b is a plan view of a DRAM device comprising a vertical channel transistor wherein (3) the intervals between adjacent word lines is reduced to one-half (½) compared to (1) the width of the word line, (2) the width of the bit line, and (4) the intervals between adjacent bit lines. In this case, (3) the intervals between adjacent word lines become the minimum feature size F, and this minimum feature size F is determined by the level of technological advancement at the time of manufacturing, resulting in an increase in the area of unit cell (12F2=4F×3F). In other words, it is never preferable to adjust the intervals between adjacent word lines in order to reduce the area of unit cell.

However, in the present invention, the horizontal interval between the adjacent first word lines and second word lines can be adjusted to any extent when the interval between adjacent first and second word lines and the interval between adjacent second word lines each has a minimum feature size F or greater. This is because word lines formed in different planes (different heights) are formed in different processes, and thus not affected by the minimum feature size, which is determined by the technology level at the time of manufacturing. In theory, it is possible to adjust the horizontal interval between the adjacent first word lines and second word lines up to ½F.

Therefore, the DRAM device according to an aspect of the present invention may achieve an improved capacity per unit area compared to the capacity per unit area which can be generally achieved at the level of technical progress at the time of manufacturing.

The technical reasons why smooth current flow can be achieved by applying current to a control electrode are described in more details below.

First, for the case where only the switching insulating layer is formed between the channel pattern and the capacitor, a change in current density according to a potential difference between the channel pattern and the capacitor is described below.

The current-voltage characteristics for the physical thicknesses of the SiO₂ layer that is widely used as an insulating layer in the field of DRAM devices are illustrated in FIG. 1.1 in the paper (Muhammad Mustafa Hussain, ADVANCED FABRICATION PROCESSES FOR SUB-50 nm CMOS, The university of Texas at Austin, December 2005). Referring thereto, when changing the potential difference from 0 V to 3 V, the current density increases about 10⁸ fold for the thickness of 1.5 nm and about 10⁷ fold for the thickness of 2 nm. That is, it can be expected that a change in current density of about 10⁷ fold or more, at least 10⁶ fold or more can be achieved without the help of the control electrode, when the switching insulating layer has a thickness that can provide a pathway for electrons to move by tunneling, channeling, etc.

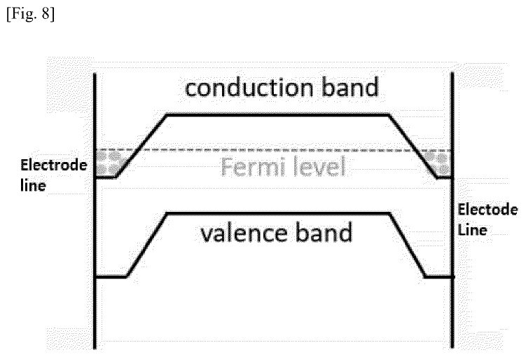

Next, a change in density current according to application of current to the control electrode is described below. FIG. 8 illustrates an energy band inside a switching insulating layer.

The Fermi level lies approximately in the middle of the energy band gap. When the bottom of the conduction band is lower than the Fermi level, electrons are concentrated in the conduction band, and a movement pathway of electrons is formed. As the switching insulating layer has a very small thickness, the electrons concentrated in the conduction band may come from the contact plug (storage node) that the switching insulating layer contacts or from the upper electrode (n+ region), as well as from inside the switching insulating layer.

For example, when applying a voltage of about 5 V to the control electrode, the bottom of the conduction band is located below the Fermi level (4.55 V) since the energy band gap of the SiO₂ layer is 9.1 V. If a substance having a small energy band gap (e.g., high-k substance), not SiO₂, is used for the switching insulating layer, a movement pathway of electrons may be formed even when the voltage applied to the control electrode is 5 V or less.

Once a movement pathway of electrons is formed in the conduction band, the electrons move from the conduction band, and current flows according to the equation V=IR. A much larger amount of current than the amount of current by tunneling, etc., flows.

Accordingly, it can be easily expected that a change in current density in the conduction band is significantly greater (at least 10⁶ fold or greater) than the change in current density by tunneling.

Next, current by the control electrode and current in a DRAM cell are compared. When the capacitance Cs of a DRAM cell capacitor is 5 fF, a drive voltage is 1 V, and a write time is 10 ns, the current in the DRAM cell can be calculated as below.

$$\frac{capacitor capacitance per cell \times drive voltage}{Write time} = \frac{5 \times {10}^{- 15} F \times 1 V}{10 \times {10}^{- 9} sec} = 0.5 μ A \qquad [ Equation 1 ]$$

In FIG. 1.1 in the paper described above, the current density is about 20 A/cm² when the thickness of the SiO₂ layer is 1.5 nm, and the drive voltage is 1 V. Accordingly, the current (current passing through the switching insulating layer when a voltage is not applied to the control electrode) can be calculated by multiplying said current density by the cross-sectional area of the channel pattern (radius of 7 nm), as indicated below.

$$Gate current density = 20 A / {cm}^{2} \times π \times {( 7 \times {10}^{- 7} cm )}^{2} = 3.0772 \times {10}^{- 11} A \qquad [ Equation 2 ]$$

When multiplying the obtained current value by the change in current density 10⁶ fold, it is calculated as 30.772 μA. This value is greater than 0.5 μA, which is the current in the DRAM cell. Considering the change in current density in the conduction band is significantly greater than the change in current density by tunneling, as described above, it can be confirmed that modification of the conduction band by the control electrode may allow sufficient current flow in the DRAM cell.

The foregoing description of the present specification has been presented for illustrative purposes, and it is apparent to a person having ordinary skill in the art that the present specification can be easily modified into other detailed forms without changing the technical idea or essential features of the present specification. Therefore, it should be understood that the forgoing embodiments are by way of example only, and are not intended to limit the present specification. For example, each component which has been described as a unitary part can be implemented as distributed parts. Likewise, each component which has been described as distributed parts can also be implemented as a combined part.

The scope of the present specification is presented by the accompanying claims, and it should be understood that all changes or modifications derived from the definitions and scopes of the claims and their equivalents fall within the scope of the present specification.

### DESCRIPTION OF REFERENCE NUMERALS

10: substrate
20: bit line
30: word line
40: channel pattern
40l: lower electrode
40u: upper electrode
50: gate
52: gate insulating pattern
54: gate conducing pattern
60: switching insulating layer
65: spacer layer
70: control electrode
80: contact plug
90: capacitor
100: vertical channel transistor
200: semiconductor device

What is claimed is:

1. A DRAM device, comprising:
a substrate;
a plurality of bit lines located on the substrate, and disposed parallel to each other in a first horizontal direction at predetermined intervals;
a plurality of word lines located on the bit line, and disposed parallel to each other in a second horizontal direction substantially perpendicular to the first horizontal direction at predetermined intervals;
a plurality of channel patterns arranged in a honeycomb structure on the bit line, the plurality of channel patterns each extending in a vertical direction;
a gate insulating pattern located between the plurality of channel patterns and the plurality of word lines;
a plurality of switching insulating layers each formed on an upper surface of each of the plurality of channel patterns, at least a portion of which has a thickness that an electron can penetrate upon application of a voltage; and
a plurality of control electrodes disposed parallel to each other at predetermined intervals to connect the plurality of switching insulating layers,
wherein the plurality of word lines comprise a first word line and a second word line respectively disposed at different heights, and the first and second word lines are provided alternating with each other in the first horizontal direction, and
the plurality of channel patterns located on the single bit line are arranged in zigzag along both edges of the single bit line, and the plurality of channel patterns contacting the single word line are arranged in a straight line.

2. The DRAM device of claim 1, wherein at least a portion of each channel pattern is in direct contact with the substrate.

3. The DRAM device of claim 1, wherein the plurality of control electrodes are disposed parallel to each other in the second horizontal direction.

4. The DRAM device of claim 1, wherein the control electrode has a thickness greater than the thickness of the switching insulating layer.

5. The DRAM device of claim 1, wherein the switching insulating layer comprises at least one selected from the group consisting of silicon oxide (SiO₂), titanium oxide (TiO₂), aluminum oxide (Al₂O₃), nickel oxide (NiO, NiO₂, Ni₂O₃), copper oxide (Cu₂O, CuO), zirconium oxide (ZrO₂), manganese oxide (MnO, MnO₂, Mn₂O₃, Mn₃O₄, Mn₂O₇), hafnium oxide (HfO₂), tungsten oxide (WO, WO₂, WO₃, W₂O₃), tantalum oxide (Ta₂O₅), niobium oxide (Nb₂O₅) and iron oxide (FeO, Fe₂O₃, Fe₃O₄).

6. The DRAM device of claim 1, further comprising a spacer layer formed on at least a portion of a side surface of the plurality of channel patterns to electrically insulate the plurality of channel patterns from the plurality of control electrodes.

7. The DRAM device of claim 1, wherein each of the plurality of channel patterns comprises an upper electrode and a lower electrode, wherein the lower electrode is in contact with the bit line.

8. The DRAM device of claim 1, further comprising a gate electrode arranged between the word line and the gate insulating pattern.
